(19) United States
(12) Patent Application Publication
(10) Pub. No.: US 2019/0297428 A1
(43) Pub. Date: Sep. 26, 2019

(54) METHOD AND WAFER FOR FABRICATING TRANSDUCER DEVICES

(71) Applicant: Cirrus Logic International Semiconductor Ltd., Edinburgh (GB)

(72) Inventors: Marek Sebastian PIECHOCINSKI, Edinburgh (GB); Tsjerk Hans HOEKSTRA, Edinburgh (GB)

(73) Assignee: Cirrus Logic International Semiconductor Ltd., Edinburgh (GB)

(21) Appl. No.: 16/302,978

(22) PCT Filed: Jun. 30, 2016
(86) PCT No.: PCT/GB2016/051971

§ 371 Date: Nov. 19, 2018

Related U.S. Application Data
(60) Provisional application No. 62/343,238, filed on May 31, 2016.

(51) Int. Cl. H04R 19/00; H04R 31/00; B81B 3/00; B81C 1/00

(52) U.S. Cl. CPC H04R 19/005; H04R 31/00; B81B 3/007; B81B 2201/0257; H04R 2201/003; B81B 2203/0127; B81C 1/00658

(57) ABSTRACT

A wafer for use in fabricating a plurality of individual transducer devices comprises a bracing structure for partitioning the wafer into a plurality of regions, and a plurality of transducer devices fabricated in one or more of the plurality of regions.

### TECHNICAL FIELD

The embodiments described herein relate to a method and wafer for fabricating transducer devices, for example a method and wafer for fabricating transducer devices such as MEMS transducer devices either with or without associated integrated electronics, including for example MEMS capacitive microphones.

### BACKGROUND OF THE INVENTION

Consumer electronics devices are continually getting smaller and, with advances in technology, are gaining ever-increasing performance and functionality. This is clearly evident in the technology used in consumer electronic products and especially, but not exclusively, portable products such as mobile phones, laptop computers, MP3 players and personal digital assistants (PDAs). Requirements of the mobile phone industry for example, are driving the components to become smaller with higher functionality and reduced cost. It is therefore desirable to integrate functions of electronic circuits together and combine them with transducer devices such as microphones and speakers.

One result of the above is the emergence of micro-electrical-mechanical-systems (MEMS) based transducer devices. These may be for example, capacitive transducers for detecting and/or generating pressure/sound waves or transducers for detecting acceleration. There is also a continual drive to reduce the size and cost of these devices.

Microphone devices formed using MEMS fabrication processes typically comprise a moveable membrane and a static backplate, with a respective electrode deposited on the membrane and the backplate, wherein one electrode is used for read-out/drive and the other is used for biasing, and wherein a substrate supports at least the membrane and typically the backplate also. In the case of MEMS pressure sensors and microphones, the read out is usually accomplished by measuring the capacitance between the membrane and backplate electrodes. In the case of transducers, the device is driven, i.e. biased, by a potential difference provided across the membrane and backplate electrodes.

FIG. 1a shows a basic MEMS transducer device 1 comprising a substrate 3 having a membrane 5 formed thereon. The substrate 3 comprises a back-volume 7. The back-volume 7 is formed using an etching process from below the substrate, known as a “back-etch”. The back-volume 7 forms an important part of a MEMS device, since the back-volume enables the membrane to move freely in response to incident sound or pressure waves.

The substrate has a width “X” and a height “Y”. For example, the width X may be typically 1.5 mm, and the depth Y typically 625 μm. The diameter of the membrane 5 is typically 1 mm.

Although not shown in FIG. 1a, it will be appreciated that, in order to incorporate the transducers into useful devices, it is necessary to interface or couple them to electronic circuitry (not shown), which may either be located on the same substrate or a separate integrated circuit.

FIG. 1b shows a view of the MEMS transducer device 1 from underneath the substrate 3, having a back-volume 7 etched therein. The back-volume has a diameter of typically 600 μm to 700 μm.

Transducer devices such as those shown in FIGS. 1a and 1b are fabricated in volume on a wafer, for example a semiconductor wafer such as a silicon wafer, whereby several thousand transducer devices are processed in parallel on the wafer, before being singulated into individual transducer devices either with or without associated integrated electronics.

There is a continual drive to reduce the overall size of MEMS devices, particularly when such devices are to be incorporated into portable electronic equipment. However, as will be appreciated, reducing the size, and in particular the height, of the MEMS device has the consequential effect of reducing the size and hence volume of the back-volume 7. That is, one method of reducing the height of the device is to reduce the thickness of the substrate 3, for example by using thinner wafers, and this will cause the back-volume 7 to reduce in size also. Reducing the size of the back-volume 7 can have a degrading effect on the output signals produced by the MEMS device 1. It will therefore be appreciated that a trade-off exists between the size and performance of the MEMS device.

One way of overcoming the drawback of reducing the back-volume when reducing the height of the MEMS device is to increase the diameter or area of the back-volume 7, such that a reduction in height is offset by the increased diameter or area. However, the amount by which the diameter or area of the back-volume 7 can be increased is limited by the diameter of the membrane. For example, with the dimensions given as examples in FIGS. 1a and 1b, the area of the back-volume 7 cannot be increased significantly above 600 μm to 700 μm, since the diameter of the membrane is typically only 1 mm.

FIG. 2a shows a MEMS transducer 1 as disclosed in patent WO 2009/024762 by the present applicant. The MEMS transducer 1 of FIG. 2a comprises a substrate 3 with a membrane 5 formed thereon. The MEMS device 1 has a back-volume formed from a first back-volume portion 7a and a second back-volume portion 7b. The first back-volume portion 7a has a first cross-sectional area or diameter, while the second back-volume portion has a second cross-sectional area or diameter 7b. The provision of the first back-volume portion 7a and the second back-volume portion 7b has the advantage of enabling the effective volume of the back-volume to be retained, even when reducing the overall height of the transducer. The first and second back-volume portions 7a, 7b also enable the overall volume of the back-volume (7a, 7b) to be increased, if desired, without being constrained by the diameter of the membrane 5.

The cross-sectional area of the first back-volume portion 7a is different to the cross sectional area of the second back-volume portion 7b in a plane where the first back-volume portion 7a and the second back-volume portion 7b meet.

The cross-sectional area of the second back-volume portion 7b is made greater than the cross-sectional area of the first back-volume portion 7a. The cross-sectional area of the second back-volume portion 7b can also be made greater than the cross-sectional area of the membrane 5.

That is, the back-volume 7 comprises a step between the first back-volume portion 7a and the second back-volume portion 7b, in which there is a discontinuity in the cross-sectional area of the back-volume going from the first portion 7a to the second portion 7b.

In this manner the overall volume of the back-volume of the MEMS transducer can be increased using the second back-volume portion 7b, i.e. by increasing its cross-sectional area (for example its diameter in the case of a back-volume having a circular cross-section).

The height of the substrate can be reduced, for example, from 625 μm to under 300 μm, for example by using a thinner wafer, and the effective volume of the back-volume retained or increased by enlarging the cross-sectional area of the second back-volume portion 7b.

The first and second back-volume portions, 7a and 7b respectively, are each created by bulk micromachining of the substrate, wherein the substrate is silicon for example. Bulk micromachining is a process used to produce micromachinery or microelectromechanical systems (MEMS). Unlike surface micromachining, which uses a succession of thin film deposition and selective etching, bulk micromachining defines structures by selectively etching inside a substrate. Whereas surface micromachining creates structures on top of a substrate, bulk micromachining produces structures inside a substrate.

FIG. 2b shows the MEMS transducer of FIG. 2a from underneath, illustrating the first back-volume portion 7a and the second back-volume portion 7b.

As mentioned above, MEMS transducer devices such as those described above are fabricated in volume on a wafer, for example using wafer level processing techniques. For example, a single wafer may be used to fabricate thousands of individual MEMS transducer devices.

There is a continual drive to reduce wafer thicknesses during fabrication, i.e. whereby the wafers are made thinner. For example, there is move to provide wafer thinning from 750 um to about 300 μm, and later to 160 μm, which can significantly alter the structural rigidity of the wafer. In particular, thinning a silicon wafer will make it less rigid and more flexible, which can lead to disadvantages, both to the manufacturing process, and to the transducer/electronic devices being fabricated.

This is particularly problematic when manufacturing MEMS transducer devices such as those described in FIGS. 2a and 2b using wafer level processing, whereby the effect of a reduced wafer thicknesses is enhanced by the manner in which the MEMS transducer devices have an extended cavity 7b defined therein. This can lead to the wafers becoming warped, or cause sagging during manufacture, i.e. because of the even thinner regions within the MEMS devices being manufactured. For example, the etched regions in the wafer can lead to less surface area being available for creating a vacuum when a wafer is “held” in place during manufacturing, e.g. during a lithography process, which can lead to misalignment issues when etching. In other words, a distorted or floppy wafer can result in a non-uniform deposition of a resist layer, which in turn can result in the depth of UV exposure being varied, which can lead to variations in mask features. This can cause a spread in manufacturing tolerances.

For example, FIG. 3a and FIG. 3b show a plan view and a side view, respectively, of a wafer 30, having a plurality of transducer devices formed therein. It will be appreciated that a wafer will typically comprises many more transducer devices in reality, but fewer are shown in the Figures for the purpose of clarity. FIG. 3c shows an example of a through hole etch for a portion “A” of the wafer from FIG. 3a corresponding to where a transducer device, such as a MEMS transducer device is fabricated, that removes a portion of the substrate material. In other words, the wafer, i.e. the substrate material, is bulk micromachined so as to selectively remove material from the wafer. The selective removal of the substrate material in this portion “A”, as with the selective removal of substrate material from a plurality of other similar transducer devices being formed on the remainder of the wafer 30, adds to the wafer, i.e. substrate, flexibility. The dotted line in FIG. 3c illustrates how further substrate material would be removed if an extended cavity is bulk micromachined in a transducer device. FIG. 3d shows an example of a two stage etch, i.e. a two-stage bulk micromachining etch, of portions “A” and “B” of the wafer of FIG. 3a, for example corresponding to a transducer device comprising a 2×1 MEMS array, from which it can be seen that the region Ti is extremely thin, thereby adding yet further to the undesired flexibility of the wafer.

As a result, wafer sag in either a wafer processing, handling, storage and/or transportation scenario can cause processing and/or stress modulations in a MEMS layer, which can introduce cross wafer non-uniformities. An undesirable processing and/or stress change in the MEMS layers can alter microphone sensitivity and even operation, and as a result can lower the yield of MEMS microphones from a wafer.

Therefore, during wafer processing, handling, storage and/or transportation, the intrinsic stress in the MEMS layers can become altered, which influences the device performance or operation. This disadvantage will be more pronounced the larger the diameter of the wafer.

### SUMMARY OF THE INVENTION

According to the embodiments described herein, there is provided a wafer and a method of fabricating transducer devices, which reduce or avoid one or more of the disadvantages mentioned above.

According to a first aspect of the invention, there is provided a wafer for use in fabricating a plurality of individual transducer devices. The wafer comprises a bracing structure for partitioning the wafer into a plurality of regions. The wafer comprises a plurality of transducer devices fabricated in one or more of the plurality of regions.

According to another aspect of the invention, there is provided a wafer for fabricating a plurality of individual transducer devices. The wafer comprises a plurality of processing regions where a plurality of transducer devices are fabricated, wherein the plurality of processing regions are separated by a bracing structure for providing rigidity to the wafer subsequent to fabrication of the plurality of transducer devices.

According to another aspect, there is provided a method of fabricating a plurality of transducer devices on a semiconductor wafer. The method comprises forming a bracing structure in the semiconductor wafer, wherein the bracing structure partitions the semiconductor wafer into a plurality of processing regions where transducer devices are fabricated.

According to another aspect, there is provided a method of fabricating a plurality of transducer devices on a semiconductor wafer. The method comprises fabricating the transducer devices in the semiconductor wafer such that they form a plurality of regions where no transducer devices are fabricated, wherein the plurality of regions form a bracing structure for providing rigidity to the silicon wafer subsequent to fabrication of the transducer devices.

According to another aspect, there is provided a method of fabricating a plurality of transducer devices on a wafer. The method comprises partitioning the wafer into a plurality of processing regions where the transducer devices are to be fabricated, wherein the plurality of processing regions are separated by a bracing structure for providing rigidity to the wafer subsequent to fabrication of the transducer devices.

According to another aspect, there is provided a semiconductor wafer comprising a bracing structure for partitioning the wafer into a plurality of regions. The semiconductor wafer comprises a plurality of MEMS microphones fabricated in one or more of the plurality of regions, wherein at least some of the plurality of MEMS microphones comprise a back-volume that comprises a first back-volume portion and a second back-volume portion, the first back-volume portion being separated from the second back-volume portion by a discontinuity in a sidewall of the back-volume.

According to another aspect, there is provided a semiconductor wafer comprising a bracing structure for partitioning the wafer into a plurality of regions. The semiconductor wafer comprises a plurality of MEMS microphones fabricated in one or more of the plurality of regions, wherein at least some of the plurality of MEMS microphones comprise a back-volume that comprises a single back-volume portion.

### BRIEF DESCRIPTION OF THE DRAWINGS

For a better understanding of the invention, and to show more clearly how it may be carried into effect, reference will now be made, by way of example only, to the accompanying drawings in which:

FIG. 1a is a schematic view of a MEMS device;

FIG. 1b is a schematic view of the MEMS device of FIG. 1a from underneath;

FIG. 2a is a schematic view of another MEMS device;

FIG. 2b is a schematic view of the MEMS device of FIG. 2a from underneath;

FIG. 3a is a plan view of a wafer;

FIG. 3b is a side view of a wafer;

FIG. 3c is a side view through a portion of a wafer, illustrating an example of a transducer device fabricated therein;

FIG. 3d is a side view through a portion of a wafer, illustrating another example of a transducer device fabricated therein;

FIG. 4a illustrates an example of a wafer comprising a bracing structure according to an embodiment;

FIG. 4b illustrates another example of a wafer comprising a bracing structure according to an embodiment;

FIG. 5 illustrates another example of a wafer comprising a wafer bracing structure according to an embodiment;

FIG. 6 illustrates another example of a wafer comprising a wafer bracing structure according to an embodiment;

FIG. 7 illustrates another example of a wafer comprising a wafer bracing structure according to an embodiment;

FIG. 8 illustrates another example of a wafer comprising a wafer bracing structure according to an embodiment;

FIG. 9 illustrates another example of a wafer comprising a wafer bracing structure according to an embodiment;

FIG. 10 illustrates another example of a wafer comprising a wafer bracing structure according to an embodiment; and

FIG. 11 shows an example of a method according to an embodiment.

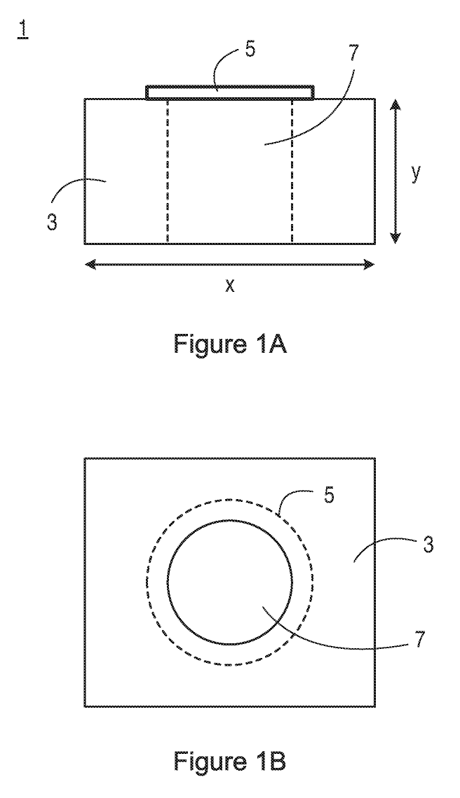

### DETAILED DESCRIPTION

The embodiments below are described in relation to a wafer, for example a semiconductor wafer such as a silicon wafer, used in the fabrication of transducer devices, for example MEMS transducer devices comprising a substrate and a membrane. It will be appreciated, however, that the invention is equally applicable to fabrication of other forms of transducer or electronic devices, including MEMS transducer devices having different structures, or indeed any other form of device.

The embodiments described herein are related to a wafer and method of fabrication that reduce wafer process and/or stress variation due to its sag or flexibility. The embodiments herein have an advantage of, on the one hand reducing wafer sag, while on the other not affecting wafer yield significantly i.e. by sacrificing too many MEMS die as a result of allowing space on the wafer for a bracing structure(s).

As will be described in further detail below, the embodiments herein involve partitioning a wafer into regions, such that areas of the wafer act as a bracing structure to help provide more rigidity to the overall wafer and/or within a specific region(s) of the wafer, thereby reducing deformation, flexing or sagging during processing, handling, storage and transportation scenarios.

The partitioning of the wafer into regions provides a localised stiffening within the wafer, such that individual regions of the wafer have a higher rigidity (relative to the wafer as a whole) hence helping to stabilise the processing and intrinsic stress in the transducer devices being fabricated on the wafer, for example stabilising an intrinsic stress within a MEMS layer of a MEMS device.

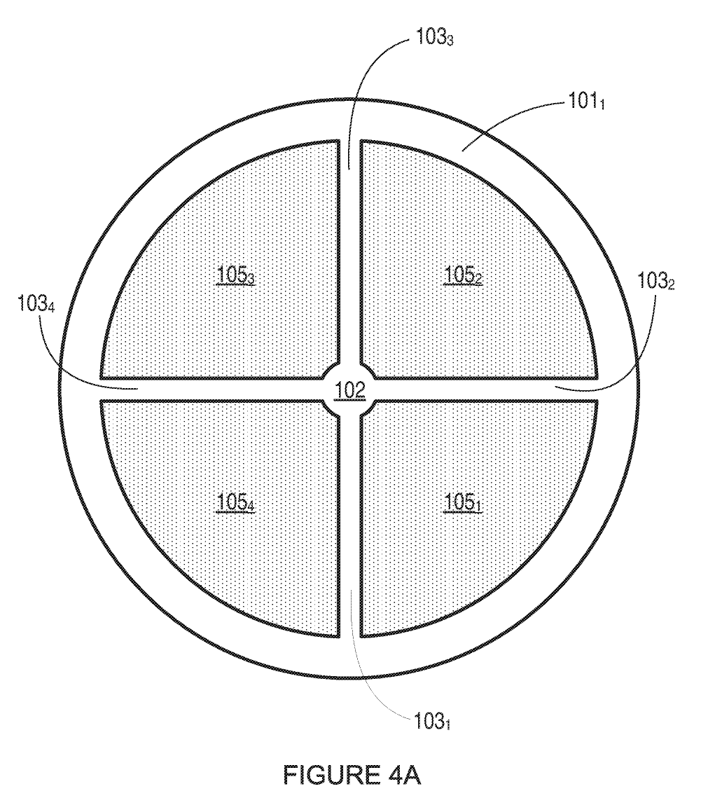

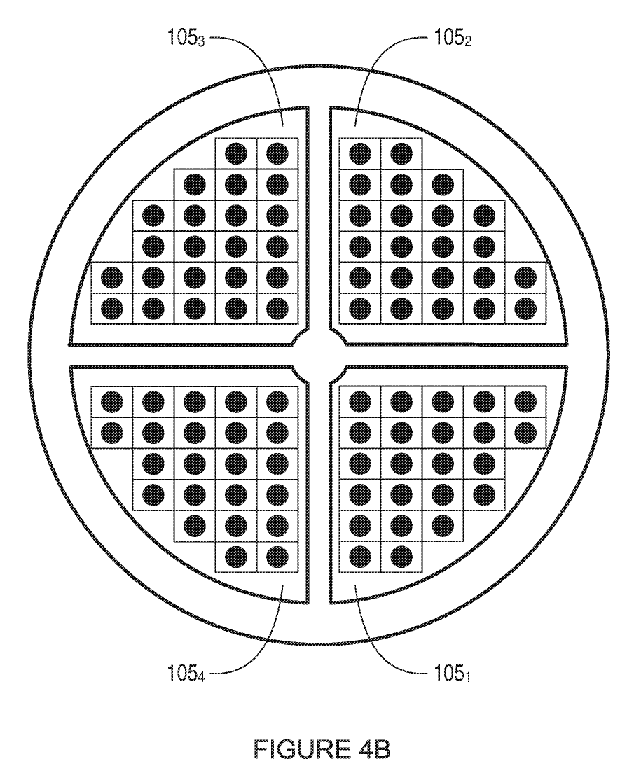

Referring to FIG. 4a, according to an embodiment, there is provided a wafer for use in fabricating a plurality of individual transducer devices (not shown). The wafer comprises a bracing structure 101, 103 for partitioning the wafer into a plurality of regions 105. The wafer comprises a plurality of transducer devices (not shown) fabricated in one or more of the plurality of regions 105.

In one embodiment, since a plurality of transducer devices are fabricated only in one or more of the plurality of regions 105 that have been partitioned using the bracing structure, the bracing structure acts to provide support and rigidity to the wafer as a whole, and/or within each region on the wafer. In some embodiments, the bracing structure 101, 103 comprises regions of the wafer where no transducer devices are fabricated within the wafer. In some embodiments, the bracing structure 101, 103 comprises regions of the wafer where no bulk micromachining is performed within the wafer.

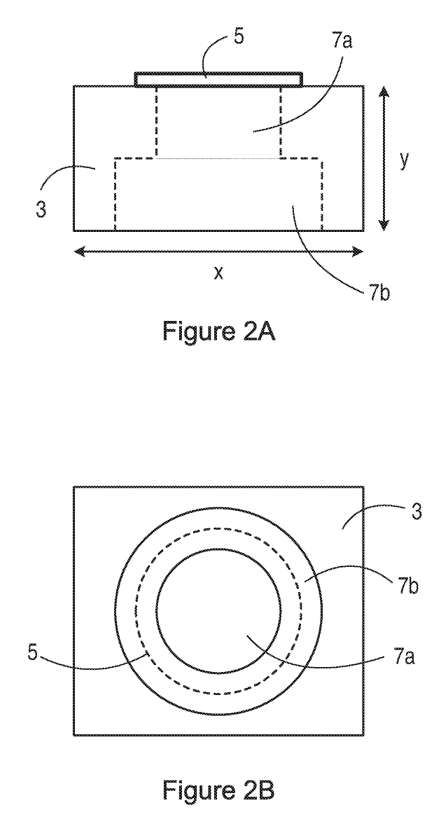

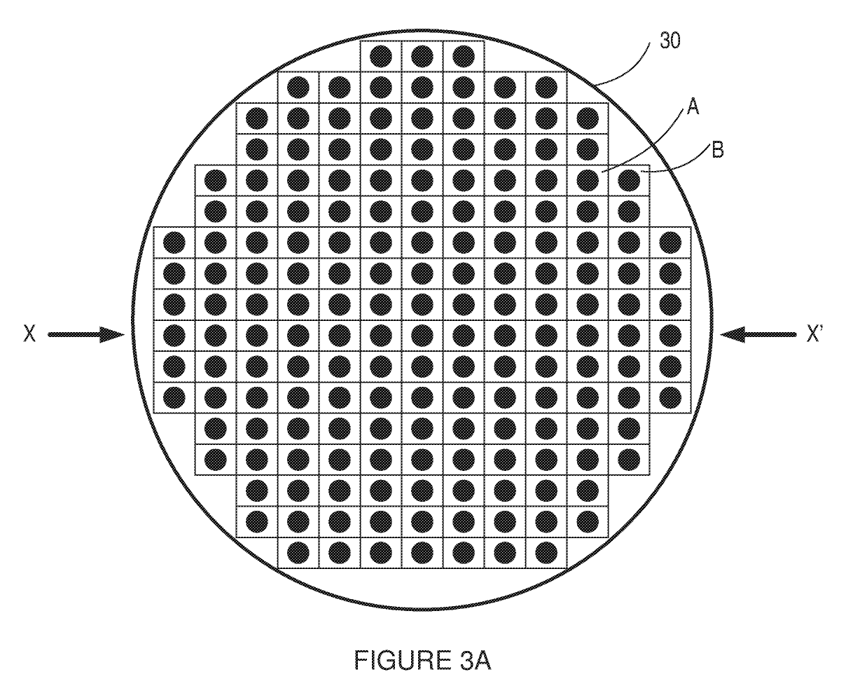

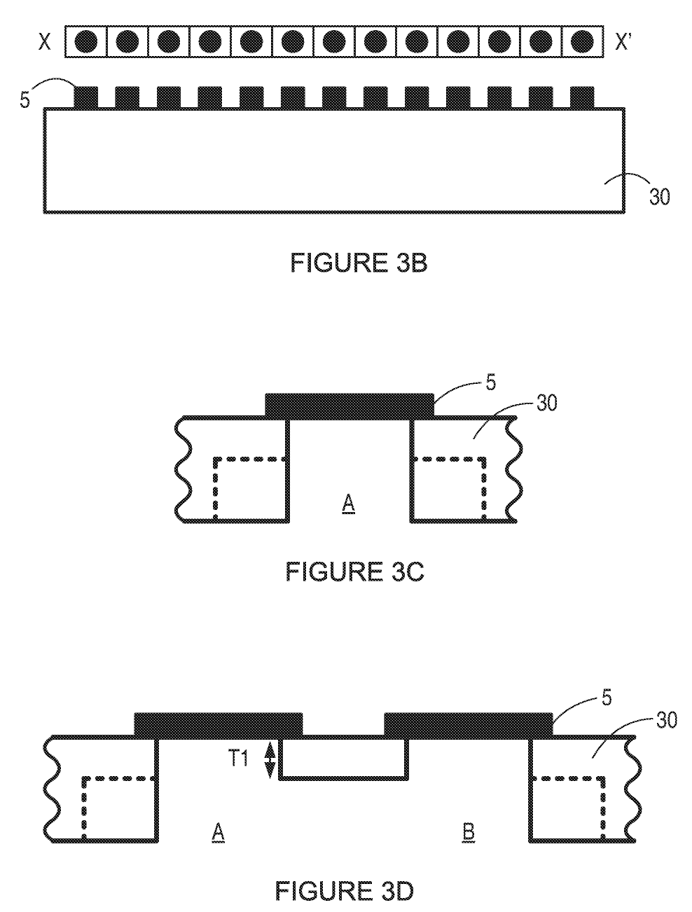

In other embodiments, the bracing structure 101, 103 comprises regions of the wafer where one or more transducer devices, or portions of one or more transducer devices, formed within, do not themselves have inherent thickness reducing structures (such as back volume portions 7a and 7b of FIG. 2a formed therein, for example using bulk micromachining or back etching techniques). In this manner, the rigidity of the wafer is improved by avoiding the placement of thickness reducing devices or regions within the areas forming the bracing structure, e.g. the non-bulk micromachined bracting structure.

The bracing structure may comprise one or more bracing rings 101₁-101_{N}.

For example, in the embodiment of FIG. 4a, the bracing structure comprises a bracing ring 101₁ that abuts or is positioned adjacent to the perimeter of the wafer. In some embodiments the bracing ring 101₁ is positioned adjacent to the perimeter of the wafer and within a predetermined distance of the perimeter. The radial thickness of the bracing ring 101₁ can be selected according to a particular application. For example the radial thickness can be increased to provide more rigidity in the wafer if the transducer devices being fabricated on the wafer are ones with large etched areas themselves. In the embodiment of FIG. 4a the bracing structure further comprises radial bracing components 103₁ to 103₄, which may also be referred to as cross-beams. The radial bracing components 103₁ to 103₄ extend from a center portion 102 of the wafer to the perimeter of the wafer, and couple or interconnect with the bracing ring 101₁. In this example the radial bracing components 103₁ to 103₄ are equally spaced in a circumferential direction around the wafer. Since there are four radial bracing components 103₁ to 103₄ in this example, they are therefore spaced at 90 degrees apart. In other non-illustrated examples, three radial bracing components could be employed and could be spaced 120 degrees apart or five radial bracing components could be employed and could be spaced 72 degrees apart, and so on and so forth.

It is noted that the bracing structure may comprise any number of bracing rings 101₁ to 101_{N} and any number of radial bracing components 103₁ to 103_{M}. In addition, although the example of FIG. 4a has the radial bracing components equally spaced, they can be arranged differently depending on a particular application, for example what type of fabrication process or handling is involved, or what type of transducer devices are being fabricated.

Therefore, according to some embodiments, in their broadest sense the bracing structure comprises one or more bracing rings 101₁-101_{N} and/or at least one radial bracing component 103₁ to 103_{M} configured to extend in a radial direction from a center portion of the wafer towards the perimeter of the wafer.

The center portion 102 may interconnect with the at least one radial bracing component 103₁ to 103_{M}.

The bracing structure of FIG. 4a partitions the wafer into a plurality of regions 105₁ to 105₄ where transducer devices are fabricated. Put another way, the layout of where the transducer devices are fabricated in a plurality of regions 105₁ to 105₄ define the shape of the bracing structure 101, 103.

FIG. 4b shows an example of a similar embodiment, illustrating how the plurality of transducer devices may be fabricated within the at least one region 105₁ to 105₄. It is noted that each region 105₁ to 105₄ may comprise thousands of such transducer devices, whereas only a limited number are shown in enlarged format for clarity and illustrative purposes.

In some embodiment, dummy transducer devices may be fabricated in areas corresponding to where the bracing structure exists, and/or within a predetermined threshold distance within the border of a particular partitioned region. The dummy transducer devices may comprise transducer devices which are fabricated in a similar manner to other transducer devices on the wafer, but whereby the dummy transducer devices do not have any through hole etch, for example no bulk micromachining. As such, the areas corresponding to the bracing structure, and/or within a predetermined threshold distance within the border of a particular partitioned region, are areas of solid unperforated wafer.

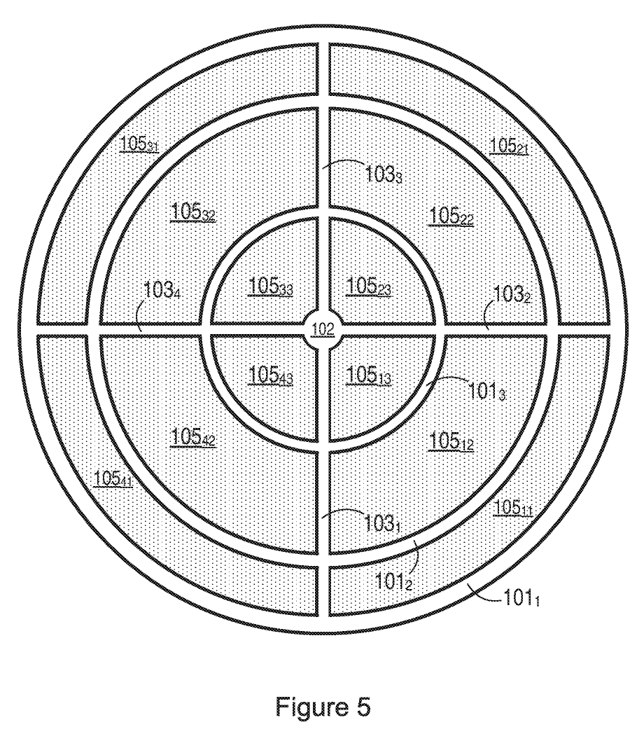

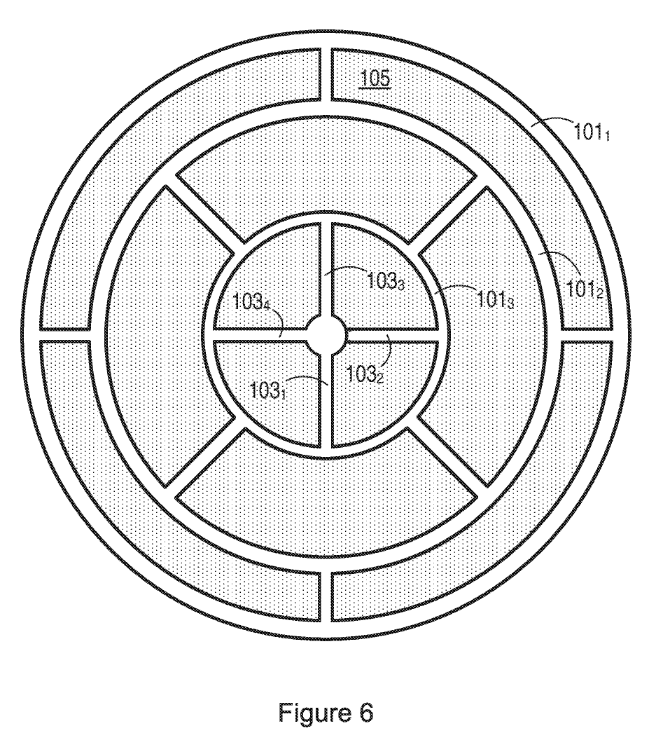

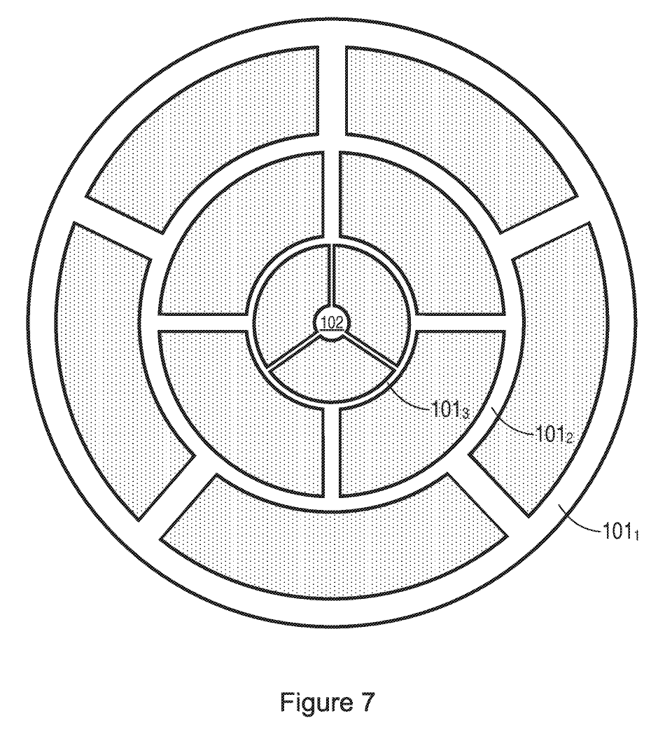

FIG. 5 shows an example of another embodiment. The embodiment of FIG. 5 comprises a plurality of concentric bracing rings 101₁-101_{N}, and in particular three concentric bracing rings 101₁-101₃ in this example. The plurality of concentric bracing rings 101₁-101_{N} may be of substantially the same radial thickness. In other examples, one or more of the plurality of concentric bracing rings 101₁-101_{N} may have a different radial thickness to the other concentric bracing rings. In the example of FIG. 5 the concentric bracing ring 101₁ that abuts the perimeter of the wafer has a thicker radial thickness that the inner concentric bracing rings 101₂ and 101₃.

In some examples the one or more concentric bracing rings 101₁-101_{N} are evenly spaced between the center and the perimeter of the wafer. In other examples, the spacing of the concentric bracing rings can be distributed non-evenly, for example whereby the concentric bracing rings are configured to be more closely spaced to each other the closer the concentric bracing rings are to the perimeter of the wafer.

The one or more concentric bracing rings 101₁-101_{N} form concentric bands (105_{X1}, 105_{X2} and 105_{X3} in this example) between each pair of concentric bracing rings, where transducer devices are fabricated.

The bracing structure of the embodiment of FIG. 5 further comprises radial bracing components 103₁ to 103₄ configured to extend in a radial direction from the center portion 102 of the wafer towards the perimeter of the wafer. In this embodiment the radial bracing components 103₁ to 103₄ extend from the center portion 102 of the wafer to the perimeter of the wafer, through each of the concentric bracing rings 101₁ to 101₃, thereby interconnecting the bracing rings 101₁ to 101₃.

In the embodiment of FIG. 5 the four radial bracing components 103₁ to 103₄ are equally spaced in a circumferential direction around the wafer. Furthermore, each radial bracing component 103₁ to 103₄ extends from the center of the wafer to the perimeter of the wafer, interconnecting each of the concentric bracing rings 101₁ to 101₃.

The bracing structure therefore partitions the wafer into a plurality of regions 105 where transducer devices are fabricated. For example, in the bottom right quadrant of FIG. 5, the wafer is partitioned into regions 105₁₁, 105₁₂, 105₁₃. As noted earlier, the bracing structure may comprise any number of concentric bracing rings 101, and/or any number of radial bracing components 103.

FIG. 6 shows an example of another embodiment. In a similar manner to FIG. 5, the embodiment of FIG. 6 comprises a plurality of concentric bracing rings 101₁ to 101₃. As with FIG. 5, in this example the concentric bracing ring 101₁ that abuts the perimeter of the wafer has a thicker radial thickness than the inner concentric bracing rings 101₂ and 101₃. It is noted, however, that the plurality of concentric bracing rings 101₁-101₃ may be of substantially the same radial thickness, or have other combinations of thicknesses. As with FIG. 5, the one or more concentric bracing rings 101₁-101₃ may be evenly spaced between the center and the perimeter of the wafer, or distributed in a non-even manner.

The bracing structure of the embodiment of FIG. 6 further comprises a plurality of radial bracing components 103 configured to extend in a radial direction from the center of the wafer towards the perimeter of the wafer. However, in this embodiment the radial bracing components 103 extend from the center portion 102 of the wafer to the perimeter of the wafer, such that a first of the plurality of radial bracing components, e.g. 103₁, extends in a direction from the center portion 102 of the wafer to the perimeter of the wafer, interconnecting a first set of concentric bracing rings, e.g. interconnecting concentric bracing rings 101₁ and 101₂ in this example, while a second of the plurality of radial bracing components, e.g. 103₂, extends in a direction from the center portion 102 of the wafer to the perimeter of the wafer, interconnecting a second set of concentric bracing rings, e.g. interconnecting concentric bracing rings 101₂ and 101₃ in this example.

In one example, the first and second radial bracing components referred to above are adjacent bracing components. The embodiment of FIG. 6 provides such radial bracing components in an alternating manner around the wafer. For example, the first and second radial bracing components may be interleaved in a circumferential direction.

In some examples, interconnections between the first set of concentric bracing rings are interleaved in a circumferential direction with interconnections between the second set of concentric bracing rings.

In the embodiment of FIG. 6 each of the radial bracing components 103 also connects the center portion 102 of the wafer to the inner concentric bracing ring 101₃. It is noted that other variations may be provided.

Therefore, as with FIG. 5, the bracing structure partitions the wafer into a plurality of regions 105 where transducer devices are fabricated (only one region 105 labelled for clarity in FIG. 6).

In the embodiments of FIGS. 5 and 6, it is noted that the bracing structure comprises a central portion 102, for example a circular portion.

It should be appreciated that the number of radial bracing components between concentric bracing rings may differ.

For example, referring to the embodiment of FIG. 7, between the central portion 102 of the wafer and the innermost concentric bracing ring 101₃ there are three radial bracing components, between the innermost bracing ring 101₃ and the next outer concentric bracing ring 101₂ there are four radial bracing components, and between the outermost bracing ring 101₁ of the wafer and the next inner concentric bracing ring 101₂ there are five radial bracing components. This embodiment illustrates that the inner regions of the wafer are inherently more rigid than the outer regions, and as such the number of radial bracing components and their respective thicknesses can be reduced towards the center of the wafer compared to the outer part of the wafer. An outer band of the wafer may comprise more radial bracing components compared to an inner band of the wafer, in order to reduce the respective areas of each region within the outer band, for example such that they correspond to the areas of each region within an inner band.

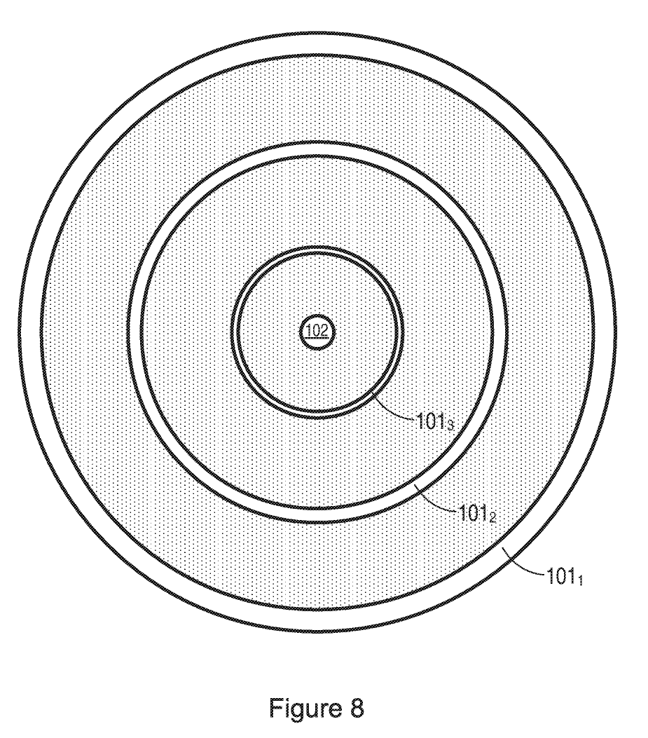

FIG. 8 shows an example of an embodiment comprising only bracing rings 101₁ to 101₃ and a central portion 102.

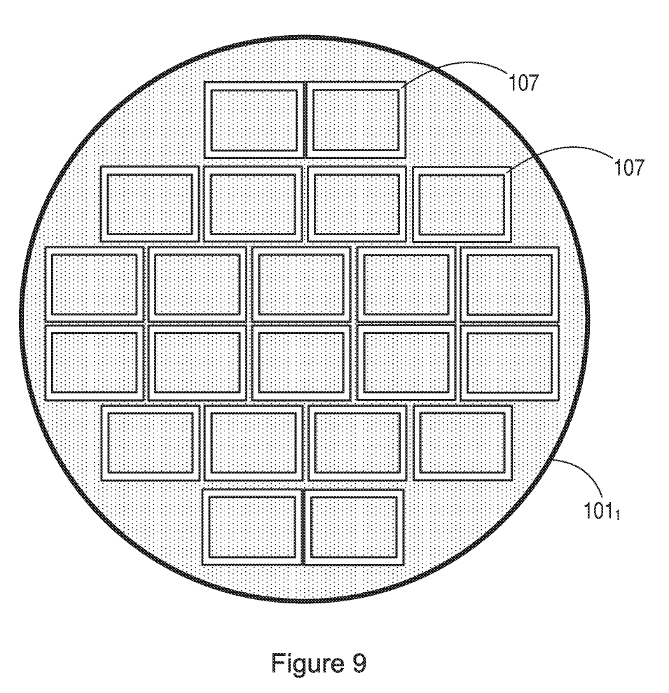

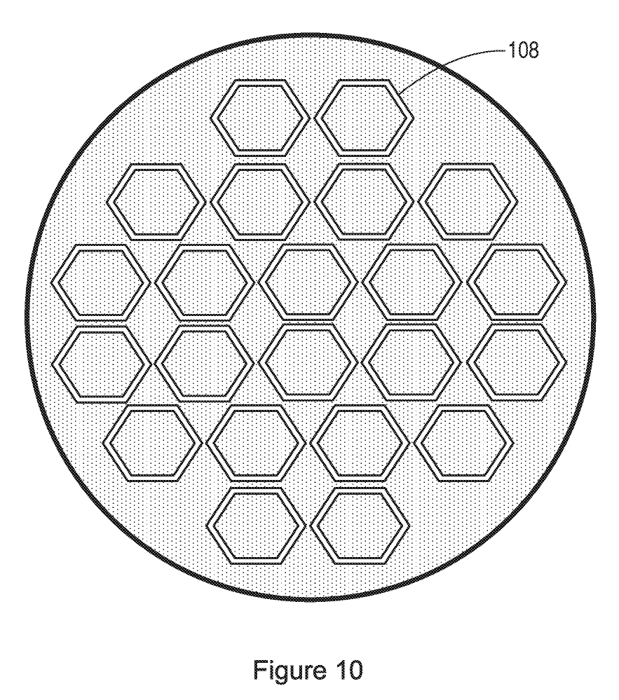

FIG. 9 shows an arrangement according to another embodiment. In this embodiment the bracing structure comprises a plurality of rectangular bracing elements 107 distributed within the perimeter of the wafer, wherein each rectangular bracing element 107 defines a region where transducer devices are fabricated. The example of FIG. 9 also comprises a bracing ring 101₁ around the periphery of the wafer. Other shapes may be used, for example a plurality of square bracing elements distributed within the perimeter of the wafer, each square bracing element defining a region within which transducer devices are fabricated.

FIG. 10 shows an example in which the bracing structure comprises a honeycomb structure, for example a plurality of hexagonal bracing elements 108 distributed within the perimeter of the wafer, each hexagonal bracing element 108 defining a region within which a plurality of transducer devices may be fabricated.

In the embodiments described herein, within a particular region defined by the bracing structure a mechanical stress within a transducer device fabricated in that particular region may be substantially uniform with the mechanical stress of another transducer device fabricated in that particular region.

In another embodiment there is provided a wafer for fabricating a plurality of individual transducer devices. The wafer comprises a plurality of processing regions where a plurality of transducer devices are fabricated. The plurality of processing regions are separated by a bracing structure for providing rigidity to the wafer subsequent to fabrication of the plurality of transducer devices.

In the embodiments described herein, it is noted that a wafer may comprise, for example, a silicon wafer.

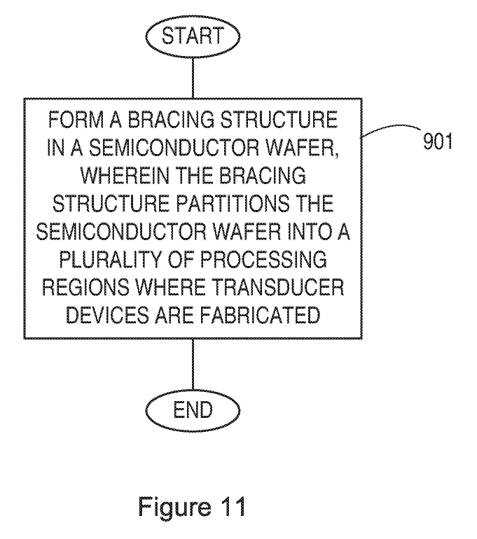

Referring to FIG. 11, according to another aspect there is provided a method of fabricating a plurality of transducer devices on a semiconductor wafer, for example a silicon wafer.

The method comprises forming a bracing structure in the semiconductor wafer, step 901, wherein the bracing structure partitions the wafer into a plurality of processing regions where transducer devices are fabricated. The method may comprise fabricating a plurality of transducer devices within one or more of the regions defined by the bracing structure.

The step of forming the bracing structure may comprises forming one or more concentric bracing rings 101₁-101_{N}.

The step of forming one or more concentric bracing rings may comprise forming one or more concentric bracing rings 101₁-101_{N} that are of substantially the same radial thickness.

In some examples, the step of forming the one or more concentric bracing rings comprises forming one of the concentric bracing rings 101₁ to abut a perimeter of the wafer, or be formed within a predetermined distance of the perimeter of the wafer.

In some examples, the step of forming the one or more concentric bracing rings comprises forming the one or more concentric bracing rings 101₁ to 101_{N} such that they are evenly spaced between the center and the perimeter of the wafer, or more closely spaced to each other the closer the concentric bracing rings are to the perimeter of the wafer.

Forming the one or more concentric bracing rings may comprise forming transducer devices within concentric bands, wherein the concentric bands define the one or more concentric bracing rings 101₁ to 101_{N}.

The step of forming the bracing structure may comprise forming at least one radial bracing component 103₁ to 103_{M} to extend in a radial direction from the center of the wafer towards the perimeter of the wafer. For example, the step of forming the at least one radial bracing component may comprise forming at least one radial bracing component 103₁ to 103_{M} to extend from a center portion of the wafer to the perimeter of the wafer, through at least one of the one or more concentric bracing rings 101₁-101_{N}. In such a method the at least one bracing component 103 acts to interconnect at least a first and second concentric bracing ring.

In another example, the step of forming the at least one radial bracing component comprises forming at least one radial bracing component 103₁ to 103_{M} to extend from a center portion of the wafer to the perimeter of the wafer, through each of the one or more concentric bracing rings 101₁-101_{N}. In such a method the at least one bracing component 103 acts to interconnect all of the concentric bracing rings.

In some examples the method comprises forming two or more radial bracing components, wherein the two or more radial bracing components are equally spaced in a circumferential direction around the wafer.

In one example, forming the at least one radial bracing component comprises forming four radial bracing components 103₁ to 103₄ such that the four radial bracing components are equally spaced in a circumferential direction around the wafer, and such that each radial bracing ring component 103₁ to 103₄ extends from the center of the wafer to the perimeter of the wafer, through each of the one or more concentric bracing rings 101₁-101_{N}.

In another example, forming the at least one radial bracing component comprises forming a plurality of radial bracing components 103₁ to 103_{M} such that the plurality of radial bracing components are equally spaced in a circumferential direction around the wafer, and a first of the plurality of radial bracing components (103₁ to 103_{M}) extends in a direction from the center of the wafer to the perimeter of the wafer, interconnecting a first set of concentric bracing rings 101₁-101_{N}, and a second of the plurality of radial bracing components 103₁ to 103_{M} extends in a direction from the center of the wafer to the perimeter of the wafer, interconnecting a second set of concentric bracing rings 101₁-101_{N}.

The first and second radial bracing components may be formed as adjacent bracing components.

The method may comprise forming the bracing structure such that interconnections between a first set of concentric bracing rings are interleaved in a radial direction with interconnections between a second set of concentric bracing rings.

In another embodiment, the step of forming the bracing structure comprises forming a plurality of rectangular bracing elements distributed within the perimeter of the wafer such that each rectangular bracing element defines a region, or forming a plurality of square bracing elements distributed within the perimeter of the wafer such that each square bracing element defines a region, or forming a plurality of hexagonal bracing elements distributed within the perimeter of the wafer such that each hexagonal bracing element defines a region.

In the embodiments of the method described herein, within a particular region defined by the bracing structure, a mechanical stress within a transducer device fabricated in that particular region is substantially uniform to the mechanical stress of another transducer device fabricated in that particular region.

In some examples the step of forming a bracing structure may comprise fabricating transducer devices in certain areas of the wafer, such that the bracing structure becomes defined in areas of the wafer where no transducer devices are fabricated. In other examples, the bracing structure comprises regions of the wafer where one or more transducer devices, or portions of one or more transducer devices, formed within, do not themselves have inherent thickness reducing structures.

In some embodiments the step of forming the bracing structure may comprise using an etching mask to protect the regions where the bracing structure is to be formed. For example, the etching mask may comprise an etching mask used to etch through holes in the plurality of transducer devices.

According to another embodiment, there is a method of fabricating a plurality of transducer devices on a semiconductor wafer, for example a silicon wafer. The method comprises fabricating the transducer devices within the wafer such that they form a plurality of regions where no transducer devices are fabricated, wherein the plurality of regions form a bracing structure for providing rigidity to the wafer subsequent to fabrication of the transducer devices.

According to another embodiment, there is provided a method of fabricating a plurality of transducer devices on a wafer. The method comprises partitioning the wafer into a plurality of processing regions where the transducer devices are to be fabricated, wherein the plurality of processing regions are separated by a bracing structure for providing rigidity to the wafer subsequent to fabrication of the transducer devices.

The wafer and method described above may be used to fabricate any form of transducer device. In some embodiments, the transducer devices fabricated in the wafer are MEMS transducers, for example MEMS microphones, whereby part of the MEMS microphone is etched away to provide a back volume.

For example, a transducer device fabricated in a wafer according to the embodiments described herein may comprise a micro-electrical-mechanical system (MEMS) transducer comprising: a substrate; a back-volume formed in the substrate; and a membrane formed over the back-volume and on the substrate; wherein the back-volume comprises a first back-volume portion and a second back-volume portion, the first back-volume portion being separated from the second back-volume portion by a step in a sidewall of the back-volume.

In one example the step in the sidewall may comprise substantially a right angle. In another example the step in the sidewall may comprise a discontinuity in the cross-sectional area of the back volume in a plane parallel to the substrate. In another example the step in the sidewall may comprise a discontinuity in a rate of change of cross-sectional area of the back volume in a plane parallel to the substrate with distance from the membrane. In some examples the step in the sidewall is curved. In some examples the step in the sidewall comprises a change in the gradient of the sidewall. In some examples, the step in the sidewall comprises two or more changes in the gradient of the sidewall.

The first back-volume portion may have a cross-sectional area that is smaller than the cross-sectional area of the membrane in a plane where the first back-volume portion and the membrane meet. The cross-sectional area of the second back-volume portion may be greater than the cross-sectional area of the membrane.

In some embodiments the first back-volume portion comprises substantially vertical walls or, alternatively, sloped walls. In some embodiments the second back-volume portion comprises substantially vertical walls or, alternatively, sloped walls.

In some embodiments the back-volume further comprises a third back-volume portion.

According to another embodiment, there is provided a semiconductor wafer comprising a bracing structure for partitioning the wafer into a plurality of regions, and a plurality of MEMS microphones fabricated in one or more of the plurality of regions. At least some of the plurality of MEMS microphones comprise a back-volume that comprises a first back-volume portion and a second back-volume portion, the first back-volume portion being separated from the second back-volume portion by a discontinuity in a sidewall of the back-volume.

The bracing structure may comprise a plurality of MEMS microphones that comprise no back-volume portion.

According to another embodiment there is provided a semiconductor wafer comprising a bracing structure for partitioning the wafer into a plurality of regions, and a plurality of MEMS microphones fabricated in one or more of the plurality of regions. At least some of the plurality of MEMS microphones comprise a back-volume that comprises a single back-volume portion.

The bracing structure may comprise a plurality of MEMS microphones that comprise no back-volume portion.

The bracing structures described herein are particularly advantageous for providing rigidity in a wafer when manufacturing transducer devices such as the MEMS transducers described above, for example rigidity within each particular region of the wafer.

Controlling the wafer stiffness via the bracing structures described herein has the advantage of allowing for higher and more stable production yield.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A wafer for use in fabricating a plurality of individual transducer devices, the wafer comprising:
a bracing structure for partitioning the wafer into a plurality of regions; and
a plurality of transducer devices fabricated in each of at least one or more of the plurality of regions, wherein a transducer device fabricated in the water comprises a micro-electrical-mechanical system (MEMS) transducer, comprising:
a substrate;
a back-volume formed in the substrate; and
a membrane formed over the back-volume and on the substrate;
wherein the back-volume comprises a first back-volume portion and a second back-volume portion, the first back-volume portion being separated from the second back-volume portion by a step in a sidewall of the back-volume;
wherein the bracing structure is formed from areas of the wafer where no transducer devices are fabricated within the wafer.

2. A wafer as claimed in claim 1, wherein the bracing structure comprises one or more bracing rings (101₁-101_{N}).

3. A wafer as claimed in claim 2 comprising a plurality of concentric bracing rings (101₁-101_{N}), and wherein the plurality of concentric bracing rings (101₁-101_{N}) are of substantially the same radial thickness.

4. A wafer as claimed in claim 2, wherein one of the concentric bracing rings (101₁) abuts a perimeter of the wafer, or is positioned adjacent to the perimeter of the wafer and within a predetermined distance of the perimeter.

5. A wafer as claimed in claim 2, wherein the one or more concentric bracing rings (101₁-101_{N}) are configured to be:
evenly spaced between the center and the perimeter of the wafer; or
more closely spaced to each other the closer the concentric bracing rings are to the perimeter of the wafer.

6. A wafer as claimed in claim 2, wherein the one or more concentric bracing rings (101₁-101_{N}) form concentric bands between each pair of concentric bracing rings where transducer devices are fabricated.

7. A wafer as claimed in claim 1, wherein the bracing structure comprises at least one radial bracing component (103₁ to 103_{M}) configured to extend in a radial direction from the center of the wafer towards the perimeter of the wafer.

8. A wafer as claimed in claim 7, wherein the at least one radial bracing component (103₁ to 103_{M}) extends from the center of the wafer to the perimeter of the wafer, through at least one of the one or more concentric bracing rings (101₁-101_{N}).

9. A wafer as claimed in claim 7, wherein the at least one radial bracing component (103₁ to 103_{M}) extends from the center of the wafer to the perimeter of the wafer, through each of the one or more concentric bracing rings (101₁-101_{N}).

10. A wafer as claimed in claim 7, to comprising two or more radial bracing components, wherein the two or more radial bracing components are equally spaced in a circumferential direction around the wafer.

11. A wafer as claimed in claim 7, wherein the at least one radial bracing component comprises four radial bracing components (103₁ to 103₄), and wherein:
the four radial bracing components are equally spaced in a circumferential direction around the wafer; and
each radial bracing component (103₁ to 103₄) extends from the center of the wafer to the perimeter of the wafer, interconnecting each of the one or more concentric bracing rings (101₁-101_{N}).

12. A wafer as claimed in claim 7, wherein the at least one radial bracing component comprises a plurality of radial bracing components (103₁ to 103_{M}), and wherein:
the plurality of radial bracing components are equally spaced in a circumferential direction around the wafer; and
a first of the plurality of radial bracing components (103₁ to 103_{M}) extends in a direction from the center of the wafer to the perimeter of the wafer, interconnecting a first set of concentric bracing rings (101₁-101_{N}); and
a second of the plurality of radial bracing components (103₁ to 103_{M}) extends in a direction from the center of the wafer to the perimeter of the wafer, interconnecting a second set of concentric bracing rings (101₁-101_{N}).

13. A wafer as claimed in claim 12, wherein the first and second radial bracing components are adjacent bracing components.

14. A wafer as claimed in claim 12, wherein interconnections between a first set of concentric bracing rings are interleaved in a circumferential direction with interconnections between a second set of concentric bracing rings.

15. A wafer as claimed in claim 1, wherein the bracing structure comprises:
a plurality of rectangular bracing elements distributed within the perimeter of the wafer, each rectangular bracing element defining a region; or
a plurality of square bracing elements distributed within the perimeter of the wafer, each square bracing element defining a region; or
a plurality of hexagonal bracing elements distributed within the perimeter of the wafer, each hexagonal bracing element defining a region.

16. A wafer as claimed in claim 1, whereby within a particular region defined by the bracing structure, a mechanical stress within a transducer device fabricated in that particular region is substantially uniform with the mechanical stress of another transducer device fabricated in that particular region.

17.-19. (canceled)

20. A method of fabricating a plurality of transducer devices on a semiconductor wafer, the method comprising:
forming a bracing structure in the semiconductor wafer;
wherein the bracing structure partitions the semiconductor wafer into a plurality of processing regions where transducer devices are fabricated in each of the plurality of regions;
forming the plurality of transducer devices in the form of micro-electrical-mechanical system (MEMS) transducers comprising:
a substrate;
a back-volume formed in the substrate; and
a membrane formed over the back-volume and on the substrate;
wherein the back-volume comprises a first back-volume portion and a second back-volume portion, the first back-volume portion being separated from the second back-volume portion by a step in a sidewall of the back-volume; and
wherein the bracing structure is formed from areas of the wafer where no transducer devices are fabricated within the wafer.

21.-56. (canceled)
